(19) United States
(12) Patent Application Publication
(10) Pub. No.: US 2024/0347339 A1
(43) Pub. Date: Oct. 17, 2024

(54) COMPOSITE SUBSTRATE FOR FABRICATION OF BETA GALLIUM OXIDE DEVICES

(71) Applicant: Syrnatec, Inc., Middletown, CT (US)

(72) Inventors: Yash Suresh Mirchandani, Avon, CT (US); Nishita Suresh Mirchandani, Avon, CT (US); Alexander Usenko, Lake St Louis, MO (US)

(21) Appl. No.: 18/301,493

(22) Filed: Apr. 17, 2023

(51) Int. Cl. H01L 21/18; B24B 37/11; H01L 21/02; H01L 21/04; H01L 21/306; H01L 21/308; H01L 21/3205; H01L 21/321; H01L 21/324; H01L 21/67; H01L 23/14

(52) U.S. Cl. CPC H01L 21/185; B24B 37/11; H01L 21/02378; H01L 21/02532; H01L 21/02565; H01L 21/0445; H01L 21/30604; H01L 21/30625; H01L 21/3081; H01L 21/3086; H01L 21/32055; H01L 21/3212; H01L 21/324; H01L 21/67075; H01L 21/67098; H01L 23/147

(57) ABSTRACT

Methods and systems for making a composite substrate is provided. The method includes depositing a silicon layer on a surface of a silicon carbide wafer. The method includes smoothing the deposited silicon layer by Chemical Mechanical Polishing (CMP) and first annealing to produce a flat silicon surface on the silicon carbide wafer. The method includes bonding the flat silicon surface of the silicon carbide wafer with a gallium oxide wafer. The method includes second annealing the bonded silicon carbide wafer and gallium oxide wafer. The method includes thinning the bonded gallium oxide wafer to a thickness of about 2 to about 25 microns.

### TECHNICAL FIELD

The present disclosure generally relates to novel methods of producing composite substrates for the fabrication of β-Ga₂O₃ devices. The composite substrate is made by direct wafer bonding of silicon carbide (SiC) substrate and beta gallium oxide (β-Ga₂O₃) substrate, and further thinning of the β-Ga₂O₃ portion of the SiC-Ga₂O₃ assembly.

### BACKGROUND

Unless otherwise indicated herein, the materials described in this section are not prior art to the claims in this application and are not admitted being prior art by inclusion in this section.

β-Ga₂O₃ is a semiconductor material with a band gap of about 4.9 eV (reported values in literature vary from 4.4 to 5.3 eV—Higashiwaki, Masataka, and Shizuo Fujita, 10 eds. Gallium Oxide: Materials Properties, Crystal Growth, and Devices. Vol. 293. Springer Nature, 2020, p. 4.). The wider bandgap of β-Ga₂O₃ may be superior for power semiconductor devices such as those used in solar inverters, or electric vehicle inverters.

β-Ga₂O₃ also has a critical electrical field strength of ˜8 MV/cm which may allow for production of high voltage devices. β-Ga₂O₃ is an oxide and may be etched chemically by either wet or plasma recipes. β-Ga₂O₃ has a lower hardness compared to nitrides and carbides such as GaN and SiC and β-Ga₂O₃ hardness may be about equal to that of silicon. Mainstream silicon grinding, lapping, polishing, and Chemical Mechanical Polishing (CMP) or planarization tools may be used for β-Ga₂O₃ with only minor processing changes required. β-Ga₂O₃ has a low thermal conductivity of 11-27 W/m·K which is around ten orders of magnitude lower than a thermal conductivity of silicon (156 W/m·K) and may be a restriction when fabricating high power semiconductor devices.

Production of β-Ga₂O₃ may be cost effective, related to crystal growth, over production of other semiconductor materials such as GaN and SiC. Since β-Ga₂O₃ is an oxide and not a carbide or a nitride, β-Ga₂O₃ may be grown using the same tools as used for other oxide semiconductors and production of β-Ga₂O₃ crystals and wafers may be more suited for fast scale up to mainstream silicon level quantities and produce high crystal quality of wafers. High β-Ga₂O₃ crystal quality may result in higher yield of semiconductor devices fabricated. β-Ga₂O₃ crystals may be less fragile compared to SiC or GaN crystals and β-Ga₂O₃ wafers may not include defects such as scratches. β-Ga₂O₃ may have low diffusion coefficients of dopants and device processing by doping by diffusion may not be feasible, but β-Ga₂O₃ may have high enough diffusion coefficients for typical dopants such as Sn, Ge, Si, as well as for compensating dopants such as Fe. Doping of β-Ga₂O₃ may be done by diffusion and ion implantation. β-Ga₂O₃ also may only have n-type dopants available and may not have p-type dopants which may limit the design of semiconductor devices from β-Ga₂O₃ to only unipolar devices such as Schottky diodes and FET transistors.

### SUMMARY

Existing challenges associated with the foregoing, as well as other challenges, are overcome by the presently disclosed composite substrate with β-Ga₂O₃ bonding to a thermally conductive SiC wafer.

One embodiment of the present disclosure is a method of making a composite substrate. The method includes depositing a silicon layer on a surface of a silicon carbide wafer. The method includes smoothing the deposited silicon layer by Chemical Mechanical Polishing (CMP) and first annealing to produce a flat silicon surface on the silicon carbide wafer. The method includes bonding the flat silicon surface of the silicon carbide wafer with a gallium oxide wafer. The method includes second annealing the bonded silicon carbide wafer and gallium oxide wafer. The method includes thinning the bonded gallium oxide wafer to a thickness of about 2 to 25 microns.

In aspects, the method further includes dividing the gallium oxide layer into islands with a size of about 2 centimeters.

In aspects, dividing the gallium oxide layer into islands includes placing a lithography mask and photoresist on the bonded gallium oxide wafer and exposing the lithography mask and photoresist to light to etch the photoresist into etched photoresist islands and expose windows of the gallium oxide layer. The method further includes etching the exposed windows of the gallium oxide layer to generate the gallium oxide islands and stripping the lithography mask and etched photoresist islands from the gallium oxide islands.

In aspects, the thinning of the gallium oxide wafer includes grinding, isotropic wet etching, and CMP.

In aspects, the first annealing includes annealing in an oxygen free environment at a temperature in a range of about 1100° C. to about 1400° C. for about 10 minutes or longer.

In aspects, the first annealing includes annealing the silicon layer on the surface of the silicon carbide wafer in a hydrogen or argon environment.

In aspects, the wetting agent is a layer with a thickness of about 1 nanometer or less.

In aspects, the wetting agent is antimony.

In aspects, the deposited silicon layer is about 5 nm to about 50 nm in thickness.

In aspects, the gallium oxide is β-Ga₂O₃.

In aspects, the second annealing includes heating the bonded silicon carbide wafer and gallium oxide wafer to a temperature of about 300° C. to about 450° C.

The present disclosure also provides a system for producing a composite substrate. The system includes Chemical Mechanical Polishing (CMP) tools, a deposition chamber, an annealing chamber, a high vacuum wafer bonding tool, and grinding and wet etching tools. The system is configured to planarize, by the CMP tools, a surface of a gallium oxide wafer and a surface of a silicon carbide wafer. The system is configured to deposit, by the deposition chamber, a wetting agent and a silicon layer on the planarized surface of the silicon carbide wafer. The system is configured to anneal, by the annealing chamber, the deposited silicon layer on the silicon carbide wafer to produce a flat silicon surface on the silicon carbide wafer. The system is configured to bond, by the high vacuum wafer bonding tool, the flat silicon surface of the silicon carbide wafer with the planarized surface of the gallium oxide wafer to produce a composite substrate. The system is configured to anneal, by the annealing chamber, the composite substrate. The system is configured to thin, by the grinding and wet etching tools, the bonded gallium oxide wafer to a thickness of about 2 microns to about 25 microns.

In aspects, the system further includes a lithography mask and photoresist, and the system is configured to define islands of gallium oxide.

In aspects, the system is further configured to place the lithography mask and photoresist on the bonded gallium oxide wafer, expose the lithography mask and photoresist to light to etch the photoresist into etched photoresist islands and expose windows of the gallium oxide layer, etch the exposed windows of the gallium oxide layer to generate the gallium oxide islands, and strip the lithography mask and etched photoresist islands from the gallium oxide islands.

Another embodiment of the present disclosure includes a composite substrate including a silicon carbide wafer and islands of gallium oxide bonded to the silicon carbide wafer. The islands of gallium oxide have a size of about 2 centimeters and a thickness of about 2 microns to about 25 microns.

### BRIEF DESCRIPTION OF THE FIGURES

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 illustrates an example system or method that can be utilized to produce a β-Ga₂O₃—SiC composite substrate according to the present disclosure;

FIG. 2 illustrates a typical surface morphology of a polycrystalline SiC wafer after Chemical Mechanical Polishing (CMP) or planarization according to the present disclosure;

FIG. 3 illustrates an example system or method that can be utilized to planarize a SiC wafer with a silicon layer according to the present disclosure; and

FIG. 4 is an exemplary process flow for dividing a continuous gallium oxide layer into die islands according to the present disclosure.

### DETAILED DESCRIPTION

The terminology used herein is for the purpose of describing particular embodiments only and is not intended to be limiting of the disclosure. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one having ordinary skill in the art to which this disclosure belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

In describing the disclosure, it will be understood that a number of techniques and steps are disclosed. Each of these has individual benefit and each can also be used in conjunction with one or more, or in some cases all, of the other disclosed techniques. Accordingly, for the sake of clarity, this description will refrain from repeating every possible combination of the individual steps in an unnecessary fashion.

Nevertheless, the specification and claims should be read with the understanding that such combinations are entirely within the scope of the disclosure and the claims.

Novel methods for producing a composite substrate and methods to make a composite substrate with β-Ga₂O₃ bonding to a thermally conductive SiC wafer are discussed herein. In the following description, for purposes of explanation, numerous specific details are set forth in order to provide a thorough understanding of the present disclosure. It will be evident, however, to one skilled in the art that the present disclosure may be practiced without these specific details.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure may comprise a composite substrate and methods to make a composite substrate with a layer of β-Ga₂O₃ bonding to a thermally conductive SiC wafer. The layer of β-Ga₂O₃ may be thinned to a thickness sufficient to withstand applied voltages. The composite substrate may have thermal sink capabilities due to the thermally conductive SiC wafer. A method of preparing a β-Ga₂O₃—SiC composite substrate may comprise bonding a β-Ga₂O₃ wafer with a SiC wafer. Prior to bonding, the surface of the β-Ga₂O₃ wafer and the SiC wafer may undergo planarization to reach a Root Mean Square (RMS) roughness below 5 Angstrom. The SiC wafer may be planarized by multiple steps including Chemical Mechanical Planarization (CMP) followed by thin film silicon deposition and further surface smoothing by annealing in hydrogen or argon ambient at about 1200° C. to about 1300° C. The prepared β-Ga₂O₃ wafer and SiC wafer may be loaded into a high vacuum wafer bonding tool. The surfaces of the β-Ga₂O₃ wafer and SiC wafer to be bonded may be bombarded with Argon ions until surface amorphization is achieved to a depth of several atomic monolayers. The surfaces of the β-Ga₂O₃ wafer and SiC wafer to be bonded may be contacted and mated at room temperature. The bonded β-Ga₂O₃ wafer and SiC wafer may be unloaded from the bonding tool. The bonded β-Ga₂O₃ wafer and SiC wafer may be heated to a temperature of about 300° C. to about 450° C. to anneal the amorphized films and strengthen the bonding between the β-Ga₂O₃ wafer and SiC wafer. While annealing, amorphized films of gallium oxide and Si within the respective β-Ga₂O₃ wafer and SiC wafer may partially epitaxially regrow in a solid-state mode and increase a strength of the bond between the β-Ga₂O₃ wafer and SiC wafer. The bonded β-Ga₂O₃ wafer and SiC wafer may form a wafer assembly with a bond sufficient to withstand grinding. The β-Ga₂O₃ side of the wafer assembly may be ground down to a thickness of about 50 microns. The β-Ga₂O₃ side of the wafer assembly may further be isotropically wet etched to remove a layer of about 25 microns of β-Ga₂O₃ which may include grinding induced cracks. The β-Ga₂O₃ side of the wafer assembly may further be processed by CMP to achieve a final gallium oxide layer with a thickness of about 2 to 25 microns.

The produced β-Ga₂O₃—SiC composite substrate may require further processing to produce gallium oxide devices as gallium oxide device manufacturing may require thermal processing at temperatures of up to about 1200° C. to about 1400° C. and a difference in thermal coefficients of expansion between β-Ga₂O₃ and SiC may result in the gallium oxide layer flaking off the SiC wafer upon at the high temperatures required for annealling. Lithography and etch steps may be performed on the β-Ga₂O₃ layer of the β-Ga₂O₃—SiC composite substrate. The lithography may be performed with lithography masks that match future individual manufacturing dies and may have characteristics or patterns with sizes from about 1 mm to about 25 mm. The lithography may also produce windows of β-Ga₂O₃ between the individual dies. The β-Ga₂O₃ in windows produced by the lithography may subsequently be etched away by reactive ion etching or by wet etch. Lithography and etching may produce a final β-Ga₂O₃—SiC composite substrate which does not develop β-Ga₂O₃ flakes or other defects during high temperature anneals.

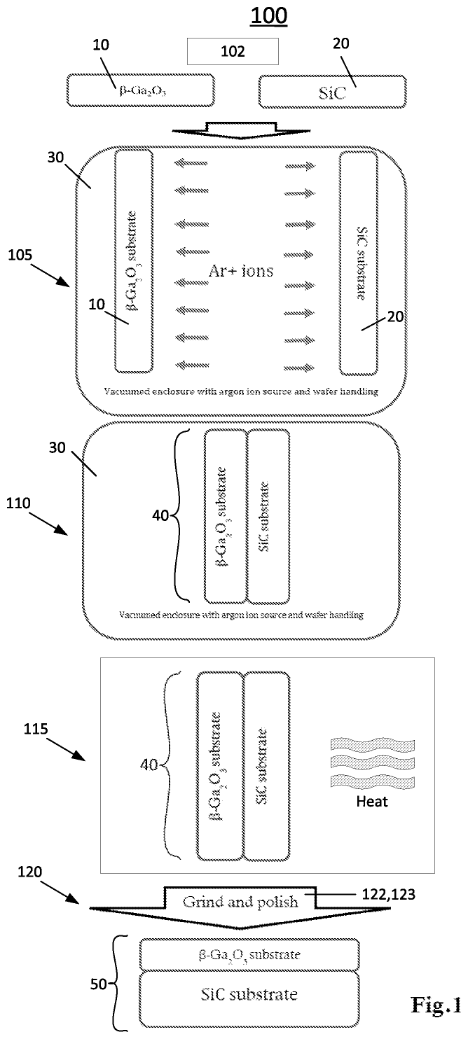

FIG. 1 illustrates an example system or method that can be utilized to produce a β-Ga₂O₃—SiC composite substrate according to the present disclosure, arranged in accordance with at least some embodiments presented herein.

System 100 may include a β-Ga₂O₃ wafer 10, a SiC wafer 20, and a high vacuum wafer bonding tool 30. A surface of β-Ga₂O₃ wafer 10 which is to be bonded to SiC wafer 20 may be planarized or polished by CMP tools. The surface of β-Ga₂O₃ wafer 10 may undergo CMP to reach a Root Mean Square (RMS) roughness below 5 Angstrom. Planarization or polishing by CMP may also be performed to a surface of SiC wafer 20 which is to be bonded to β-Ga₂O₃wafer 10. The surface of SiC wafer 20 may be planarized or polished by CMP to reach a Root Mean Square (RMS) roughness below 5 Angstrom. β-Ga₂O₃ wafer 10 may have a diameter of about 100 mm to about 300 mm and a thickness of about 650 microns to about 1.0 mm. SiC wafer 20 may have a diameter of about 100 mm to about 300 mm and a thickness of about 350 microns.

After planarization, the surface of SiC wafer 20 which is to be bonded to β-Ga₂O₃ wafer 10 may undergo thin film silicon deposition. As described in more detail below, thin film silicon deposition may include applying a wetting agent such as antimony to the surface of SiC wafer 20 which is to be bonded to β-Ga₂O₃ wafer 10 and then applying a layer of silicon to the wetting agent. The surface of SiC wafer 20 which is to be bonded to β-Ga₂O₃ wafer 10 may then be annealed in hydrogen or argon ambient at about 1100° C. to about 1400° C. for about 10 minutes or longer to produce a flat silicon surface for bonding to β-Ga₂O₃ wafer 10.

At 105, β-Ga₂O₃ wafer 10 and SiC wafer 20 may be loaded into high vacuum wafer bonding tool 30. After β-Ga₂O₃ wafer 10 and SiC wafer 20 are loaded into high vacuum wafer bonding tool 30, high vacuum wafer bonding tool 30 may generate a vacuum pressure of 10E-12 mbar or lower. High vacuum wafer bonding tool 30 may bombard the CMP treated surface of β-Ga₂O₃ wafer 10 to be bonded to SiC wafer 20 and the CMP and thin film silicon deposition surface of SiC wafer 20 to be bonded to β-Ga₂O₃ wafer 10 with argon ions at room temperature and under vacuum for a period of time sufficient to achieve surface amorphization of each wafer surface to a depth of several atomic monolayers.

At 110, high vacuum wafer bonding tool 30 may contact and mate the argon treated surface of β-Ga₂O₃ wafer 10 with the argon treated surface of SiC wafer 20 at room temperature and under vacuum to produce composite substrate 40. High vacuum wafer bonding tool 30 may maintain vacuum pressure of 10E-12 mbar or lower during bonding. High vacuum wafer bonding tool 30 may be configured to bond dissimilar wafers in a high vacuum environment, such as surface activated bonding “SAB”. High vacuum wafer bonding tool 30 may be commercially available equipment to perform SAB such as COMBOND by EV Group and BOND MEISTER by Mitsubishi Heavy Industries Machine Tool Co. High vacuum wafer bonding tool 30 may contact and mate the argon treated surface of β-Ga₂O₃ wafer 10 with the argon treated surface of SiC wafer 20 so that amorphized monolayers of material on the argon treated surface of β-Ga₂O₃ wafer 10 may interact with amorphized monolayers of silicon on the argon treated surface of SiC wafer 20. Upon mating the two surfaces, excess energy due to crystal disordering by ion bombarding may cause strong bonding between the argon treated surface of β-Ga₂O₃ wafer 10 and the argon treated silicon surface of SiC wafer 20 to produce composite substrate 40. As described above, mating surface materials that are bonded are β-Ga₂O₃ of β-Ga₂O₃ wafer 10 and flat silicon layer deposited on SiC wafer 20.

At 115, composite substrate 40 may be annealed to improve bond strength between the argon treated surface of β-Ga₂O₃ wafer 10 and the argon treated surface of SiC wafer 20 of composite substrate 40. During annealing, gallium oxide may start to epitaxially regrow in solid state mode at about the same temperature as silicon. The annealing may occur at a temperature of about 300° C. to about 450° C. even though a melting temperature of gallium oxide may be about 1900° C. which is significantly higher than a melting temperature for silicon. Annealing composite substrate 40 at a temperature of about 300° C. to about 450° C. may increase bond strength between the argon treated surface of β-Ga₂O₃ wafer 10 and the argon treated surface of SiC wafer 20 without limiting the size of composite substrate 40, as annealing at temperatures over 1000° C. may damage or break composite substrate 40 for substrate wafer sizes larger than 1 inch.

At 120, the β-Ga₂O₃ side of composite substrate 40 may be ground and polished to produce wafer assembly 50. First, the β-Ga₂O₃ side of composite substrate 40 may be ground down until the β-Ga₂O₃ side of composite substrate 40 has a thickness of about 50 microns by grinding tools 122. Next, composite substrate 40 may be isotropically wet etched by wet etching tools 123 to remove about a 25 micron layer of the remaining β-Ga₂O₃ layer. Isotropic wet etching tools 123 may remove a layer of β-Ga₂O₃ which may include grind induced cracks. Subsequently, the β-Ga₂O₃ side of composite substrate 40 may be processed with CMP to achieve a β-Ga₂O₃ layer thickness of about 2 microns to about 25 microns resulting in wafer assembly 50.

Wafer assembly 50 may be a composite substrate and may include β-Ga₂O₃ layer 60 with a thickness of about 2 microns to about 25 microns bonded to SiC wafer 20. Wafer assembly 50 may be a composite substrate suitable for Schotty diode manufacturing without further processing. As described in more detail below, wafer assembly 50 may be further processed to prepare wafer assembly 50 for high temperature processing during gallium oxide device manufacturing.

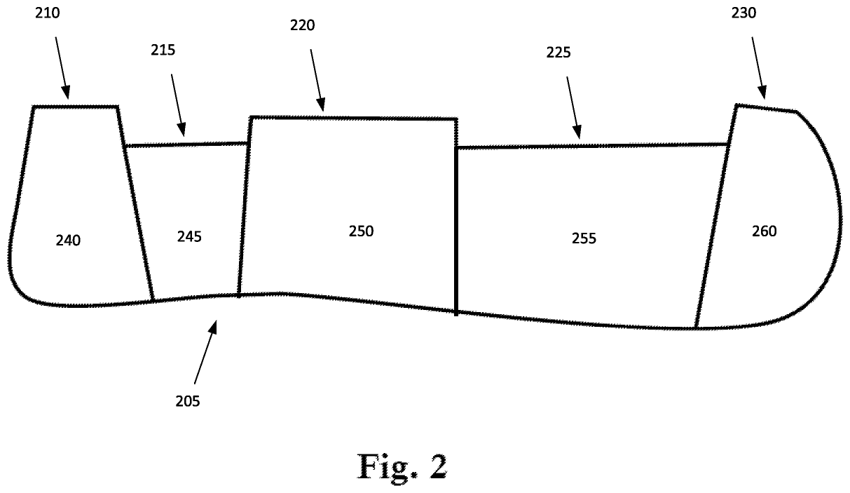

FIG. 2 illustrates a typical surface morphology of a polycrystalline SiC wafer after CMP according to the present disclosure, arranged in accordance with at least some embodiments presented herein. Those components in FIG. 2 that are labeled identically to components of FIG. 1 will not be described again for the purposes of brevity.

After CMP, a polycrystalline SiC wafer 205 may include a bonding surface with dips 215, 225 and elevated plates 210, 220, 230 and may have a surface roughness higher than 0.5 nm rms required for quality direct wafer bonding. Dips 215, 225 and elevated plates 210, 220, 230 may be due to crystals of polycrystalline SiC wafer 205 having different hardness in different directions with softer grains 245 and 255 resulting in dips 215 and 225 and harder grains 240, 250, and 260 resulting in elevated plates 210, 220, and 230. A surface of elevated plates 210, 220, and 230 may be about 1 nm above a surface of dips 215 and 225. Abrupt differences in elevation of neighboring grains 240, 245, 250, 255, and 260 may result in a wafer bond by only elevated plates 210, 220, and 230 when bonding SiC wafer 205.

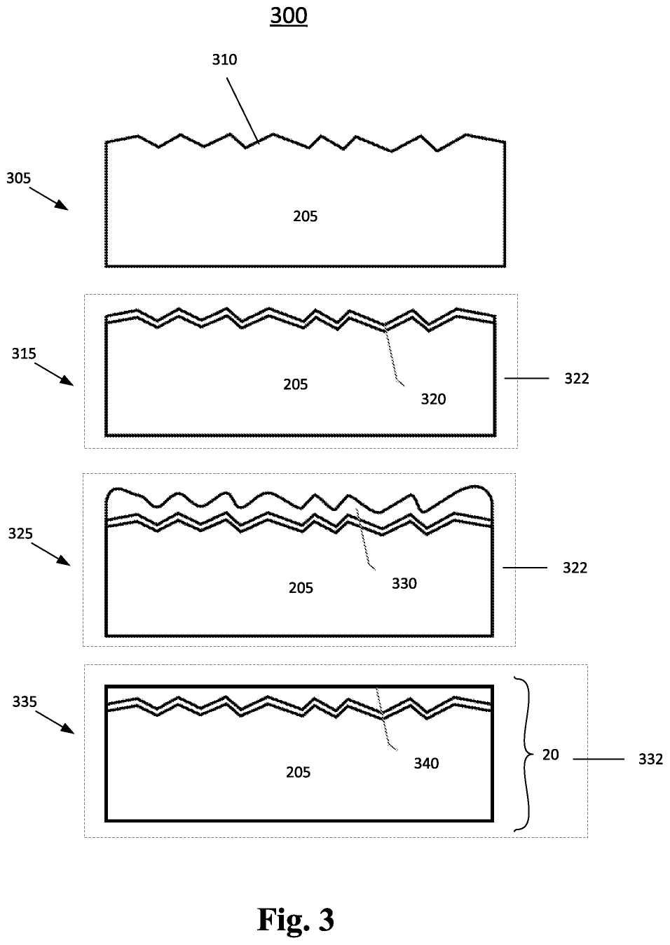

FIG. 3 illustrates an example system or method that can be utilized to planarize a SiC wafer with a silicon layer according to the present disclosure, arranged in accordance with at least some embodiments presented herein. Those components in FIG. 3 that are labeled identically to components of FIGS. 1-2 will not be described again for the purposes of brevity.

System 300 may include previously described polycrystalline SiC wafer 205. At 305, SiC wafer 205 is shown including an uneven bonding surface 310 with dips and elevated plates. Uneven bonding surface 310 may have a surface roughness higher than about 0.5 nm rms. Uneven bonding surface 310 may be a result of CMP to crystals of polycrystalline SiC within wafer 205 having different hardness in different directions, and CMP of softer grains resulting in dips while CMP of harder grains resulting in elevated plates. Bonding surface 310 of SiC wafer 205 may undergo thin film silicon deposition to provide a smooth surface for bonding.

At 315, a layer of a wetting agent 320 may be deposited onto uneven bonding surface 310. Layer of wetting agent 320 may be antimony (Sb), or any other wetting agent known in the art. Layer of wetting agent 320 may be about 1 nm or less in thickness. Deposition of layer of a wetting agent 320 may be performed in a deposition chamber 322 by any convenient method of deposition including sputtering and e-beam evaporation. Layer of wetting agent 320 may act as a n-dopant for silicon and may provide a low resistivity electrical contact when SiC wafer 205 is bonded to β-Ga₂O₃ wafer 10 as described in FIG. 1.

A 325, a layer of silicon 330 may be deposited upon layer of wetting agent 320. Layer of silicon 330 may be about 5 to about 50 nm in thickness. A layer of silicon 330 thicker than 50 nm may lower thermal sink of SiC substrate. Deposition of layer of silicon 330 may be performed in deposition chamber 322 by any convenient method of deposition including sputtering and e-beam evaporation.

At 335, SiC wafer 205 with layer of a wetting agent 320 and layer of silicon 330 may be smoothed by annealing at about 1100° C. to about 1400° C. in an oxygen free environment in annealing chamber 332, for example, in hydrogen or in argon, to produce flat silicon surface 340 on SiC wafer 20. Annealing SiC wafer 205 with layer of a wetting agent 320 and layer of silicon 330 in an oxygen free environment may increase silicon diffusion along uneven bonding surface 310 in a phenomenon called hydrogen bake which may be used in preparation for Si epitaxy. During annealing, the system may lower its enthalpy by creating atomically flat silicon surface 340. Layer of wetting agent 320 may suppress dewetting phenomenon which may occur for silicon deposited directly on uneven bonding surface 310 of SiC wafer 205 as silicon may wet at silicon terminated surfaces and may dewet at carbon terminated surfaces. If layer of silicon 330 was deposited directly on uneven bonding surface 310 of SiC wafer 205 only silicon terminated portions of uneven bonding surface 310 of SiC wafer 205 may be covered with layer of silicon 330 and carbon terminated portions of uneven bonding surface 310 of SiC wafer 205 may remain uncoated.

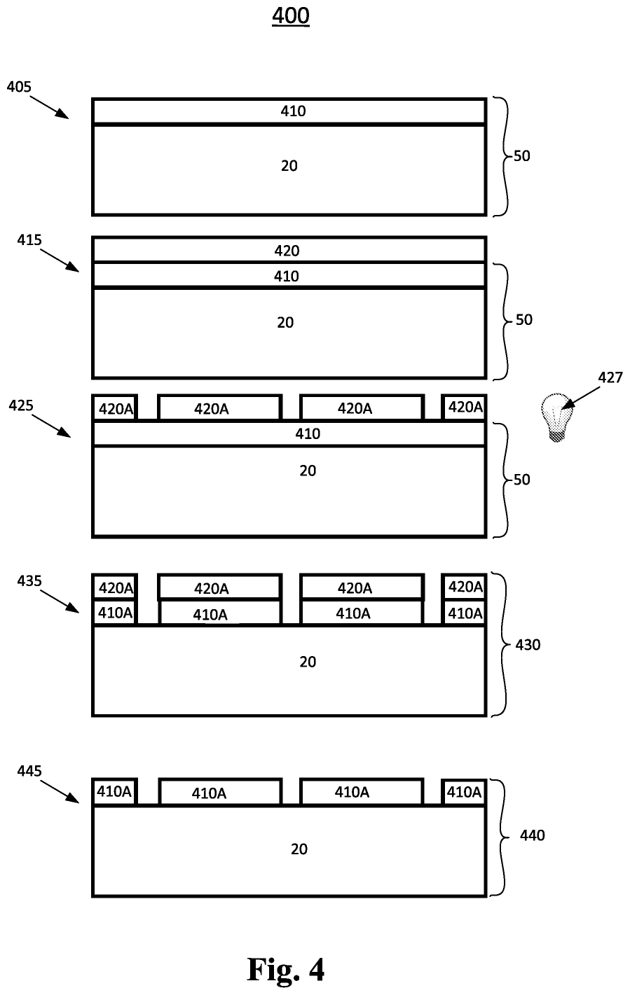

FIG. 4 is an exemplary process flow for dividing a continuous gallium oxide layer into die islands according to the present disclosure, arranged in accordance with at least some embodiments presented herein.

At 405, system 400 may include previously described wafer assembly 50. Wafer assembly 50 may include a layer of β-Ga₂O₃ 410 bonded to SiC wafer 20. Layer of β-Ga₂O₃ 410 may be about 2 to about 25 microns thick.

At 415, a lithography mask and photoresist layer 420 may be placed upon layer of β-Ga₂O₃ 410. Lithography mask and photoresist layer 420 may be any standard lithography such as contact lithography and may use any convenient photoresist such as SU-8, etc. Lithography mask and photoresist layer 420 may not require a high resolution and windows in lithography mask of lithography mask and photoresist layer 420 may be about 5 microns wide, and may define square non-etched islands of β-Ga₂O₃ of about 2×2 cm.

At 425, lithography mask and photoresist layer 420 may be exposed to light 427. Photoresist of lithography mask and photoresist layer 420 may be etched by light 427 through windows of lithography mask resulting in wafer assembly 50 with lithography mask and etched islands of photoresist 420A left on layer of β-Ga₂O₃ 410. Etched islands 420A may be in the shape of lithography mask and may be about 2×2 cm in size. The lithography may be performed with lithography and photoresist layer 420 including a lithography mask which matches future individual dies required for gallium oxide device production and lithography and photoresist layer 420 may have a lithography mask with characteristics or patterns sized from about 1 mm to about 25 mm. Lithography and photoresist layer 420 may also produce windows of exposed layer of β-Ga₂O₃ 410 between etched islands 420A.

At 435, etching may be performed on exposed layer of β-Ga₂O₃ 410 between etched islands 420A of wafer assembly 50. Etching may be reactive-ion etching with chemically reactive plasma (BCl3/Cl2+BCl3 plasma) to remove layer of β-Ga₂O₃ 410 exposed by lithography etched islands 420A from wafer assembly 50 at an etching rate of about 1 micron/minute until SiC of SiC wafer 20 is reached. The plasma may be generated under low pressure by an electromagnetic field. In another embodiment, etching may be wet etching in 85% phosphoric acid at 190° C. and an etch rate of between about 0.5 to about 1 micron/minute. Etching may remove sections of β-Ga₂O₃ layer 410 that are exposed and not covered by etched islands of photoresist 420A, resulting in wafer assembly 430 with etched islands of β-Ga₂O₃ 410A and etched islands 420A. Etched islands 410A may be the same shape as etched islands 420A and may be about 2×2 cm in size.

Lithography mask layer and photoresist etched islands 420A may be removed from wafer assembly 430 by stripping, resulting in wafer assembly 440, at 445. Wafer assembly 440 may be a composite substrate and may include SiC wafer 20 bonded with etched islands of β-Ga₂O₃ 410A, each about 2×2 cm in size, and about 2 to about 25 microns thick. Wafer assembly 440 may be a composite substrate of islands of β-Ga₂O₃ 410A bonded to SiC wafer 20. Wafer assembly 440 may be processed to fabricate gallium oxide metal-oxide-semiconductor field-effect transistor (MOSFET) semiconductor devices as wafer assembly 440 may withstand MOSFET semiconductor device processing temperatures of about 900° C. to about 1400° C. Islands of β-Ga₂O₃ 410A bonded to SiC wafer 20 may be sized as individual MOSFET die and may be smaller than 1 inch in any lateral dimension. Lithography and etching may produce a final β-Ga₂O₃—SiC composite substrate wafer assembly 440 which does not develop β-Ga₂O₃ flakes or other defects during high temperature anneals.

A system in accordance with the present disclosure may produce a composite β-Ga₂O₃—SiC wafer substrate from a low quality or inexpensive SiC single crystalline wafer. A system in accordance with the present disclosure may produce a composite β-Ga₂O₃—SiC wafer substrate from a SiC wafer with scratches on the SiC surface to be bonded. A system in accordance with the present disclosure may produce a composite β-Ga₂O₃—SiC wafer substrate by scaling micropipes that would affect the bond quality. A system in accordance with the present disclosure may produce a composite β-Ga₂O₃—SiC wafer substrate with bonding finalized at low temperature to minimize the risk of breaking the wafer assembly due to differences in the thermal expansion coefficients of the components.

A system in accordance with the present disclosure may produce a composite β-Ga₂O₃—SiC wafer substrate from SiC wafers with high defect levels that may not be suitable for other SiC device manufacturing. A system in accordance with the present disclosure may produce a composite β-Ga₂O₃—SiC wafer substrate with SiC wafer thermal conductivity of 490 W/15 m K which is more than triple silicon thermal conductivity. A system in accordance with the present disclosure may produce a composite β-Ga₂O₃—SiC wafer substrate from SiC wafers with crystalline stacking faults, micropipes (type of helical dislocation), pits, scratches, stains, surface particles, and alien (non-4H) polytype inclusions.

It should be understood that the foregoing description is only illustrative of the present disclosure. Various alternatives and modifications can be devised by those skilled in the art without departing from the disclosure. Accordingly, the present disclosure is intended to embrace all such alternatives, modifications, and variances. The embodiments described with reference to the attached drawing figures are presented only to demonstrate certain examples of the disclosure. Other elements, steps, methods, and techniques that are insubstantially different from those described above and/or in the appended claims are also intended to be within the scope of the disclosure.

1. A method of making a composite substrate, the method comprising:
depositing a silicon layer on a surface of a silicon carbide wafer;
smoothing the deposited silicon layer by Chemical Mechanical Polishing (CMP) and first annealing to produce a flat silicon surface on the silicon carbide wafer;
bonding the flat silicon surface of the silicon carbide wafer with a gallium oxide wafer;
second annealing the bonded silicon carbide wafer and gallium oxide wafer; and
thinning the bonded gallium oxide wafer to a thickness of about 2 to about 25 microns.

2. The method of claim 1, further comprising dividing the gallium oxide layer into islands with a size of about 2 centimeters.

3. The method of claim 2, wherein dividing the gallium oxide layer into islands comprises:
placing a lithography mask and photoresist on the bonded gallium oxide wafer;
exposing the lithography mask and photoresist to light to etch the photoresist into etched photoresist islands and expose windows of the gallium oxide layer;
etching the exposed windows of the gallium oxide layer to generate the gallium oxide islands; and
stripping the lithography mask and etched photoresist islands from the gallium oxide islands.

4. The method of claim 1, wherein the thinning of the gallium oxide wafer includes grinding, isotropic wet etching, and CMP.

5. The method of claim 1, wherein the first annealing includes annealing in an oxygen free environment at a temperature in a range of about 1100° C. to about 1400° C. for about 10 minutes or longer.

6. The method of claim 5, wherein the first annealing includes annealing the silicon layer on the surface of the silicon carbide wafer in a hydrogen or argon environment.

7. The method of claim 1, further comprising depositing a wetting agent prior to depositing the silicon layer on the surface of the silicon carbide wafer.

8. The method of claim 7, wherein the wetting agent is a layer with a thickness of about 1 nanometer or less.

9. The method of claim 7, wherein the wetting agent is antimony.

10. The method of claim 1, wherein the deposited silicon layer is about 5 to about 50 nm in thickness.

11. The method of claim 1, wherein the gallium oxide is β-Ga₂O₃.

12. The method of claim 1, wherein the second annealing includes heating the bonded silicon carbide wafer and gallium oxide wafer to a temperature of about 300° C. to about 450° C.

13. A system for producing a composite substrate, the system comprising:
Chemical Mechanical Polishing (CMP) tools;
a deposition chamber;
an annealing chamber;
a high vacuum wafer bonding tool; and
grinding and wet etching tools;
wherein the system is configured to:
planarize, by the CMP tools, a surface of a gallium oxide wafer and a surface of a silicon carbide wafer;
deposit, by the deposition chamber, a wetting agent and a silicon layer on the planarized surface of the silicon carbide wafer;
anneal, by the annealing chamber, the deposited silicon layer on the silicon carbide wafer to produce a flat silicon surface on the silicon carbide wafer;
bond, by the high vacuum wafer bonding tool, the flat silicon surface of the silicon carbide wafer with the planarized surface of the gallium oxide wafer to produce a composite substrate;
anneal, by the annealing chamber, the composite substrate; and
thin, by the grinding and wet etching tools, the bonded gallium oxide wafer to a thickness of about 2 to about 25 microns.

14. The system of claim 13, further comprising a lithography mask and photoresist, the system further configured to define islands of gallium oxide.

15. The system of claim 14, wherein the islands of gallium oxide are about 2×2 cm.

16. The system of claim 14, wherein the system is further configured to:
place the lithography mask and photoresist on the bonded gallium oxide wafer;
expose the lithography mask and photoresist to light to etch the photoresist into etched photoresist islands and expose windows of the gallium oxide layer;
etch the exposed windows of the gallium oxide layer to generate the gallium oxide islands; and
strip the lithography mask and etched photoresist islands from the gallium oxide islands.

17. The system of claim 13, wherein the annealing of the deposited silicon layer on the silicon carbide wafer includes annealing in an oxygen free environment at a temperature in a range of about 1100° C. to about 1400° C. for about 10 minutes or longer.

18. The system of claim 13, wherein the wetting agent is a layer of antimony with a thickness of about 1 nanometer or less.

19. The system of claim 13, wherein the annealing of the composite substrate includes heating the bonded silicon carbide wafer and gallium oxide wafer to a temperature of about 300° C. to about 450° C.

20. A composite substrate comprising:
a silicon carbide wafer, and
islands of gallium oxide bonded to the silicon carbide wafer wherein the islands of gallium oxide have a size of about 2 centimeters and a thickness of about 2 to about 25 microns.
